(19) United States
(12) Patent Application Publication
(10) Pub. No.: US 2026/0343810 A1
(43) Pub. Date: Oct. 29, 2026

(54) PCB STATOR PUMPS

(71) Applicant: HEWLETT PACKARD ENTERPRISE DEVELOPMENT LP, Spring, TX (US)

(72) Inventors: Michael Dustin Scott, Chippewa Falls, WI (US); Andrew Michael Schiessl, Eau Claire, WI (US)

(21) Appl. No.: 19/193,244

(22) Filed: Apr. 29, 2025

(51) Int. Cl. H05K 7/20; F04D 13/06; F04D 29/22; F04D 29/62

(52) U.S. Cl. CPC H05K 7/20272; F04D 13/06; F04D 29/22; F04D 29/628; H05K 7/20254; H05K 7/20772

(57) ABSTRACT

A printed circuit board (PCB) stator pump may include a conduit defining a flow path from an inlet of the conduit to an outlet of the conduit. The PCB stator pump may also include an impeller/rotor subassembly comprising an impeller and a rotor disposed in the conduit and rotatable together relative to the conduit about a rotation axis. A PCB stator may be positioned axially adjacent to the rotor and oriented perpendicular to the rotation axis such that the PCB stator may drive rotation of the rotor.

### INTRODUCTION

Some information processing systems utilize liquid cooling techniques to remove heat from the system. In these systems, a liquid coolant is circulated in a loop through the information processing devices (e.g., servers, networking devices, etc.) of the system, and heat generating components thereof (e.g., processors) are thermally coupled (e.g., via cold plates) to the liquid coolant so that the liquid coolant absorbs heat from these components. As the now-heated coolant exits the information processing devices, it carries the heat to a cooling device (such as a heat exchanger) which cools the liquid back to a desired operating temperature, whereupon the cooled liquid is circulated through the loop once again, extracting more heat from the information processing devices.

### BRIEF DESCRIPTION OF THE DRAWINGS

The present disclosure can be understood from the following detailed description, either alone or together with the accompanying drawings. The drawings are included to provide a further understanding of the present disclosure and are incorporated in and constitute a part of this specification. The drawings illustrate one or more examples of the present teachings and together with the description explain certain principles and operations. In the drawings:

FIG. 1 is a schematic block diagram illustrating an example PCB stator pump.

FIG. 2 is a schematic sectional view of a first configuration example of the PCB stator pump of FIG. 1.

FIG. 3 is a schematic sectional view of a second configuration example of the PCB stator pump of FIG. 1.

FIG. 4 is a schematic sectional view of a third configuration example of the PCB stator pump of FIG. 1.

FIG. 5 is a schematic sectional view of a fourth configuration example of the PCB stator pump of FIG. 1.

FIG. 6 is a schematic sectional view of a fifth configuration example of the PCB stator pump of FIG. 1.

FIG. 7 is a schematic sectional view of a sixth configuration example of the PCB stator pump of FIG. 1.

FIG. 8 is a is a schematic sectional view of a first pump unit comprising two of the PCB stator pumps of FIG. 1 coupled in series.

FIG. 9 is a is a schematic sectional view of a second pump unit comprising two of the PCB stator pumps of FIG. 1 with a shared PCB stator and coupled in series.

FIG. 10 is a is a schematic sectional view of a third pump unit comprising two of the PCB stator pumps of FIG. 1 with a shared PCB stator and coupled in parallel.

FIG. 11 is a schematic block diagram of an information processing device comprising the PCB stator pump of FIG. 1.

FIG. 12 is a schematic block diagram of an information processing system comprising multiple of the information processing devices of FIG. 11.

FIG. 13 is a perspective exploded view of an example PCB stator pump.

FIG. 14 is another perspective exploded view of the PCB stator pump of FIG. 13.

FIG. 15 is a perspective view of the PCB stator pump of FIG. 13.

FIG. 16 is a cross-section of the PCB stator pump of FIG. 13, with the section taken along the plane 16-16 indicated in FIG. 15.

FIG. 17 is a cross-section of another example PCB stator pump having two PCB stators and two rotors.

FIG. 18 is a cross-section of an example pump unit comprising two PCB stator pumps with a shared PCB stator.

FIG. 19 is a cross-section of another example pump unit comprising two PCB stator pumps with three PCB stators, including one shared PCB stator, and four rotors.

FIG. 20 is a cross-section of another example PCB stator pump having one PCB stator and two rotors.

### DETAILED DESCRIPTION

Liquid cooling loops generally use one or more pumps to drive the circulation of the liquid through the loop. Often, these pumps are disposed in a so-called coolant distribution unit (CDU) which provides a centralized pumping unit which circulates the liquid collectively through multiple information processing devices (e.g., an entire rack, or multiple racks, of such devices). These pumps are usually very large, with the CDU often taking up a substantial portion of a rack, or in some cases a full rack.

Many pumps comprise an impeller disposed in an impeller chamber through which liquid flows, with the impeller being rotatable and comprising blades that move the liquid through the chamber as the impeller rotates, thus generating pressure and liquid flow. The pump also comprises a motor which drives the rotation of the impeller. The motor comprises a stator, which is stationary relative to the pump housing, and a rotor, which rotates relative to the stator and which is coupled to the impeller such that rotation of the rotor drives rotation of the impeller. One of the stator and rotor (usually the rotor) comprises permanent magnets, while the other usually comprises wire windings arranged to generate magnetic fields that magnetically interact with the permanent magnets to drive the relative rotation between the rotor and stator. Often, the motor is disposed external to the impeller chamber and is connected to the rotor via a shaft that pierces through the wall of the impeller chamber.

In some cases, it may be desired to utilize relatively small pumps in liquid cooling loops, rather than the commonly used large CDU pumps. One advantage of using smaller pumps for liquid cooling information processing systems is that the smaller pumps can be more efficient than the larger pumps, in terms of the amount of liquid they can move per unit of energy spent. The smaller pumps can also fit in places that the large pumps will not, which opens opportunities for system designers to arrange their systems in new and potentially more efficient ways which would not have otherwise been possible. For example, smaller pumps can allow for a distributed pumping architecture to be utilized, in which each information processing device is provided with one or more small pumps localized to the device (e.g., disposed within, or adjacent to, the chassis of the device) to control the circulation of fluid locally through that device in an individualized manner, rather than using a single large centralized pumping unit to control the flow of fluid collectively through the devices. This distributed approach can improve efficiency and performance of the liquid cooling loop, potentially reducing power usage and noise while also delivering more coolant flow (and hence better cooling). In addition, this may also facilitate greater modularity and scalability of the system, as the pumping capacity of the system naturally scales along with the demand for cooling, since each new device added to the system brings its own pump(s) with it.

While having smaller pumps can in theory be advantageous, realizing these advantages can be challenging with existing pump technologies. Many existing pumps that can produce the needed levels of pressure and liquid flow rates for liquid cooling an information processing device are simply too large, or are too awkwardly shaped, to fit well within the densely packed environment of an information processing device. Often, the motor of the pump can be a limiting factor when it comes the size and shape of the pump. Other pumps (such as artificial heart pumps) may be small enough to fit in a space-constrained information processing system, but these generally have inadequate pumping characteristics (e.g., insufficient pressure, insufficient flow rates, poor efficiency, etc.) for the liquid cooling context. In other words, it is challenging to find pumps which both have a suitable small form factor and which have desired pumping characteristics.

In addition, the disposition of the motor external to the impeller chamber, as is common in existing pumps, can lead to further challenges. The hole through which the shaft enters the chamber can pose a risk of leakage, which may be undesirable within an information processing device which may house electronic components that could be damaged by leaking liquid. Seals may be used between the shaft and the chamber wall to reduce the chance of leakage, but the chance of leakage cannot be fully eliminated. In addition, the seals will introduce friction between the rotating shaft and the chamber wall, which can decrease efficiency of the pump and generate wear that may reduce the lifespan of the parts.

To address these challenges, the present disclosure provides printed circuit board (PCB) stator pumps, which include a motor whose stator is formed from a PCB. The motor of the PCB stator pumps also includes a rotor that is coupled to (in some cases, formed integrally with) the impeller. The rotor can be disposed within the impeller chamber in some examples, or in an adjacent chamber fluidically coupled with the impeller chamber in other examples. The PCB stator may be disposed axially adjacent to and facing the rotor, with the PCB stator perpendicular to the axis of rotation of the rotor and impeller. The stator may be disposed outside the impeller chamber in some examples, with a wall of the impeller chamber disposed therebetween. In other examples, the stator may be disposed inside the impeller chamber.

The PCB stator pumps may be capable of having a very small form factor while still providing desirable pumping characteristics. For instance, in some examples the PCB stator pumps may have a dimensional envelope with a volume of about 8 in³ (e.g., about 2 in on a side) while still being able to provide a flow rate of 2-4+gpm at a pressure of 15+psi. In contrast, a comparative pump that uses a standard DC brushless motor design may be about 2.5 times larger than the PCB stator pump while producing a flow rate of 2 gpm at a pressure of 15 psi. Note that the overall pumping potential of a pump can be divided between flow rate and pressure so to achieve a desired balance between these parameters, such as achieving a greater flow rate at a lower pressure, a lower flow rate at a higher pressure, or an intermediate flow rate at an intermediate pressure. In addition, pumping potential and size can be traded off, depending on the intended application. Thus, the numbers cited above are merely illustrative examples, and in practice example pumps disclosed herein and comparative pumps can have a variety of different pumping characteristics and a variety of different sizes depending on how they have been optimized and the applications in which they are deployed. Nevertheless, when pumps disclosed herein are compared to larger comparative pumps under similar hydraulic conditions, the pumps disclosed herein perform as well, if not better, than comparative pumps (e.g., pumps disclosed herein may achieve the same or greater flow rates at a given pressure, or the same or greater pressures at a given flow rate), or the pumps disclosed herein may greatly outperform the comparative pumps when they are same size.

As noted, in PCB stator pumps disclosed herein the stator is a PCB. This may be contrasted with other pumps in which the stator is usually formed from wire windings. The PCB stator can be relatively thin in the axial dimension, such as about 0.05-0.1 in, for example. In contrast, the axial length of the wire winding stator of the comparative pump described above may be about 1.0 in. This results in the overall axial length of the motor (stator and rotor together) being about four times larger in the comparative pump than in PCB stator pumps disclosed herein.

Furthermore, in PCB stator pumps disclosed herein the PCB stator is disposed axially adjacent to and facing the rotor. This may be contrasted with other pumps in which the stator is positioned radially outward of and circumferentially surrounding the rotor. Having the PCB stator axially adjacent to the rotor can allow for either the diameter of the impeller to be increased for a given overall pump diameter or can allow for an overall pump diameter to be smaller for a given impeller size. This is because in the PCB stator pump there is no need to position the stator radially between an outer housing of the pump and the impeller, allowing the impeller to span essentially the entire diameter of the pump. In contrast, in pumps where the stator is radially outward of and circumferentially surrounds the rotor, and where the rotor is integrated into the impeller (as in some axial pumps), the stator sits between the impeller and the outer housing and therefore the diameter of the impeller is reduced, relative to the pump diameter, by the radial thickness of the stator. A larger impeller diameter, such as provided by the PCB stator pumps disclosed herein, can allow for more efficient pump operation, meaning that less energy needs to be expended in order to generate a given flow rate. For example, some PCB stator pumps disclosed herein may be around 40-60% efficient, whereas certain comparable pumps may be about 5-12% efficient. The larger impeller diameter can also allow for the impeller to be driven at slower speeds while maintaining desired flow rates, which contributes to the aforementioned efficiency gains, as well as reducing wear (thus increasing part lifespans) and reducing noise and heat generation.

Furthermore, as noted above, in some example PCB stator pumps disclosed herein the rotor is disposed within the impeller chamber, and therefore there is no need for a shaft to pierce the impeller chamber to couple the impeller with an external rotor, as is often found in other pumps. Thus, the challenges described above stemming from a shaft piercing of the impeller chamber can be avoided with these PCB stator pumps.

In addition, in some examples the PCB stator may also be disposed in the impeller chamber, or in an adjacent chamber fluidically connected with the impeller chamber. This can allow the liquid coolant which is flowing through the pump to also flow over the stator, thus cooling the PCB stator. This may allow the pump to operate efficiently without overheating even in adverse environments where this is no (or little) opportunity for airflows to cool the pump. For example, some information processing systems are designed to be totally liquid cooled with no forced airflow through the system, and a pump deployed in such a system could easily overheat if not actively cooled. But in examples disclosed herein where the PCB stator is exposed to the liquid coolant, such overheating is unlikely, as the liquid can adequately cool the pump.

Turning now to the figures, various devices, systems, and methods in accordance with nonlimiting aspects of the present disclosure will be described.

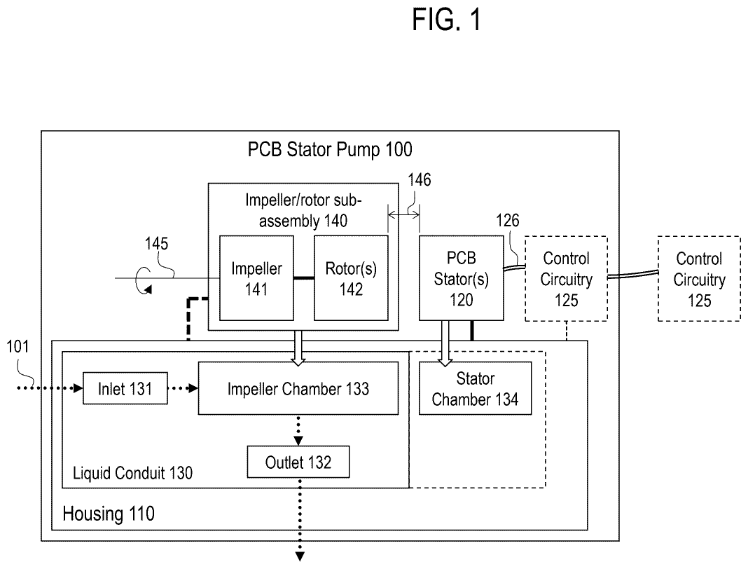

FIG. 1 is a schematic diagram conceptually illustrating a PCB stator pump 100 (also referred to herein as “pump 100”). FIG. 1 illustrates general positional and functional relationships between components, as described below, but the diagram is schematic in nature and is not intended to illustrate specific shapes, dimensions, or other structural details accurately or to scale. It should be understood that implementations of the pump 100 can vary from one another in various aspects. Some implementations of the pump 100 may have different numbers and arrangements of the illustrated components. Some implementations of the pump 100 may include other parts that are not illustrated in FIG. 1. Some implementations of the pump 100 may omit one or more of the parts that are illustrated in FIG. 1.

As shown in FIG. 1, the PCB stator pump 100 comprises a housing 110, one or more PCB stators 120, and an impeller/rotor subassembly 140 that includes an impeller 141 and one or more rotors 142. The pump 100 may also comprise control circuitry 125, in some examples. These components of the pump 100 will be described in greater detail below.

The housing 110 comprises one or more walls or other support structures that support and at least partially enclose or house some of the other components of the pump 100. In particular, housing 110 comprises a liquid conduit 130, and in some examples also comprises one or more stator chambers 134, described in turn below. The housing 110 may also comprise other walls or other support structures (not illustrated). The housing 110 may be formed from any materials which can contain the pressures expected to be generated by the pump 100. In some examples, the housing 110 may comprise one or more plastics, such as Polyphenylene Sulfide (PPS), as one example. In some examples, the housing 110 may comprise one or more metals, such as stainless steel, brass, copper, etc. In some examples, it may be beneficial for the material selected for the housing to be resistant to corrosion or other chemical reactions with the liquid coolant with which the pump 100 is expected to operate. In some examples, the housing 110 may be formed from all one material, while in other examples multiple different materials may be used to form different parts of the housing 110.

The liquid conduit 130 (also “conduit 130”) comprises walls that partially enclose a volume and define a liquid flow path through that enclosed volume, with the liquid flow path being the path along which liquid coolant 101 (also “liquid 101”) flows as it traverses the pump 100. The liquid 101 may be water (which may include deionized water, distilled water, etc.), a combination of water and other additives (e.g., ethylene glycol, propylene glycol, etc.), or any other liquid coolant suitable for liquid cooling information processing components. The liquid conduit 130 comprises an impeller chamber 133 that defines part of the enclosed volume and that houses at least the impeller 141, and in some cases the entire impeller/rotor subassembly 140. The liquid conduit 130 further comprises an inlet 131 and an outlet 132, which are both fluidically coupled to the impeller chamber 133 and to an external environment, meaning an environment external to conduit 130 (but which may be internal to some other component). The conduit 130 may be liquid tight except for allowing fluid communication into and out of the conduit 130 through openings in the inlet 131 and outlet 132.

The inlet 131 comprises at least a first opening through a wall of the impeller chamber 133, and the outlet 132 comprises at least a second opening through a wall of the impeller chamber 133. In some examples, the inlet 131 further comprises a first tube portion and a third opening in the first tube portion. The first tube portion of inlet 131 is coupled to impeller chamber 133 at the first opening and defines a first channel extending from the first opening at one end to the third opening at the other end, with the first channel forming a portion of the volume enclosed by the liquid conduit 130. Similarly, in some examples, the outlet 132 further comprises a second tube portion and a fourth opening in the second tube portion. The second tube portion of outlet 132 is coupled to impeller chamber 133 at the second opening and defines a second channel extending from the second opening at one end to the fourth opening at the other end, with the second channel forming another portion of the volume enclosed by the liquid conduit 130. In other examples, the inlet 131 and/or the outlet 132 do not include any such tube portion extending from the impeller chamber 133.

In some examples, the inlet 131 and outlet 132 are configured to be coupled to coolant lines (e.g., pipes/tubes) of a liquid cooling system, in which case the external environment referenced above to which the inlet 131 and outlet 132 fluidically connect the liquid conduit 130 may be the interior volumes of those coolant lines. The inlet 131 and/or outlet 132 may further comprise liquid coupling structures that facilitate coupling with the coolant lines. Examples of such liquid coupling structures include hose barbs, fittings, quick connect couplings, and/or other liquid coupling mechanisms as would be familiar to those of ordinary skill in the art. In some examples, the aforementioned first tube of the inlet 131 and/or second tube of the outlet 132 may be part of such a liquid coupling structure. When the pump 100 is coupled to the liquid cooling system, liquid 101 may be supplied to the inlet 131 via a coolant line coupled thereto. The liquid 101 then flows from the inlet 131 into the impeller chamber 133, traverses the impeller chamber 133, and flows out from impeller chamber 133 into outlet 132. The liquid 101 is then expelled from outlet 132 into another coolant line attached thereto. Note that liquid 101 is shown in FIG. 1 by dotted line arrows to schematically illustrate functionality of the pump 100 when deployed, but the liquid 101 is not necessarily part of the pump 100 and is not necessarily present in all states of the pump 100 (e.g., prior to being deployed for use, there might be no liquid in the pump 100).

In some examples, the impeller chamber 133 may comprise at least two parts that are initially separate and then later joined together. These parts may be assembled together and joined around the impeller/rotor subassembly 140 to form the impeller chamber 133 with the subassembly 140 contained therein. For example, the two parts may include a partial impeller chamber and a cover which is joined thereto. The partial impeller chamber may define an internal volume with an opening at one axial end thereof through which the impeller/rotor subassembly 140 can be inserted into the internal volume, and the full impeller chamber may be formed by joining the cover to the partial impeller chamber so as to close the opening. In some cases, the cover may be an end wall, which may be a shared wall between the impeller chamber 133 and the stator chamber 134. In other examples, the cover may be the stator chamber 134, in which case the stator chamber 134 may become part of the impeller chamber 133 after being joined to the partial impeller chamber. The parts that from the impeller chamber 133 may be joined together by welding (e.g., ultrasonic welding), brazing, adhesives, mechanical fasteners (e.g., bolts, latches, threaded couplings, etc.) combined with sealing elements (e.g., o-rings), or any other joining or fastening technique that can create a liquid-tight joint.

In some examples in which inlet 131 and/or outlet 132 comprise additional structures beyond the first and second opening (e.g., liquid coupling structures), these additional structures are integrally connected to at least one part of the impeller chamber 133. For example, one part of the impeller chamber 133 and the additional structures of the inlet 131 and/or outlet 132 and may be formed together as parts of the same unitary (monolithic) body, which may be formed by molding (e.g., injection molding), casting, 3D printing, machining from the same block of material, etc. In other examples, the additional structures of the inlet 131 and/or outlet 132 may be formed separately from the impeller chamber 133 and are later joined thereto, for example by welding (e.g., sonic welding), brazing, adhesives, mechanical fasteners (e.g., threaded couplings, etc.), or any other joining or fastening technique.

As mentioned, in some examples the housing 110 also comprises one or more stator chambers 134 to house one or more PCB stators 120, which will be described in more detail below. In many cases, to simplify the discussion, the description below will refer primarily to one PCB stator 120 and one stator chamber 134, but it should be understood that the descriptions could also apply to examples where multiple PCB stators 120 and/or stator chambers 124 are present. In some examples, impeller chamber 133 and stator chamber 134 may be fluidically coupled, allowing some of the liquid 101 flowing through impeller chamber 133 to enter stator chamber 134, thus flowing over and cooling PCB stator 120. In such examples, the stator chamber 134 may be regarded as being part of the liquid conduit 130. In other examples, the stator chamber 134 is fluidically isolated from impeller chamber 133 and is not part of the liquid conduit 130. In some examples, the stator chamber 134 may be a portion of the impeller chamber 133, with no barrier therebetween. In other examples, the stator chamber 134 and the impeller chamber 133 may be distinct chambers separated by one or more walls. In other examples, a stator chamber 134 is omitted, and PCB stator 120 may sit outside the impeller chamber 133 without being housed in any other chamber.

In some examples, the entire impeller/rotor subassembly 140 (both impeller 141 and any rotors 142) is disposed in the impeller chamber 133. In other examples, the impeller 141 may be disposed in the impeller chamber 133 while one or more rotors 142 may be disposed in adjacent chambers fluidically coupled with the impeller chamber 133, such as a stator chamber 134. In such examples, a shaft may extend between the chambers to connect the rotor 142 with the impeller 141, passing through a wall separating the chambers. However, this hole does not pose a risk of leakage to an external environment because the two chambers may be joined together (e.g., via ultrasonic welding, or other joining techniques) and sealed relative to and external environment forming, in essence, one large sealed chamber with two sub-compartments therein. Thus, fluid can freely communicate between the impeller chamber 133 and the adjacent chamber through this hole and/or other holes without posing any risk to leakage to an exterior environment, and therefore the hold does not need to be sealed and the friction or wear problems arising from such seals around rotatable shafts can be avoided.

The PCB stator 120 may be positioned such that it is aligned with a corresponding rotor 142 along a rotation axis 145 of the rotor 142 and spaced apart from the rotor 142 along the axis 145 with a gap 146 therebetween. This arrangement is referred to herein as the PCB stator 120 being “axially adjacent” the rotor 142. The gap 146 may comprise empty space or it may comprise intermediate structures, such as wall(s) separating the chambers 133 and 134. The smaller the size of the gap 146 in the axial dimension, the stronger the magnetic interaction between PCB stator 120 and rotor 142, but any size of gap 146 may be used that will allow for sufficient magnetic interaction between PCB stator 120 and rotor 142. In some examples, the gap 146 may beneficially be between 0.6 mm and 2.2 mm in the axial dimension, and in some of these examples is about 1.0 mm.

As mentioned, in some examples, multiple stators 120 and multiple rotors 142 are provided, in which case each stator 120 may be disposed axially adjacent a corresponding one of the rotors 142. For example, one stator 120 may be disposed on one side of the impeller chamber 133 (e.g., in one stator chamber 134), and the other stator 120 may be disposed on an opposite side of the impeller chamber 133 (e.g., in another stator chamber 134), and the impeller/rotor subassembly 140 may include two rotors disposed on opposite sides of the impeller 141 opposite from the two stators 120, respectively.

In examples in which the stator chamber 134 is part of the impeller chamber 133, PCB stator 120 and impeller/rotor subassembly 140 are collocated within the impeller chamber 133. In some of these examples, the stator chamber 134 (or a portion thereof) may correspond to one of the two parts of the impeller chamber 133 which are formed separately and then later joined, as described above.

In examples in which the stator chamber 134 and the impeller chamber 133 are distinct chambers, they may be separated by one or more walls that extend perpendicular to rotation axis 145 of impeller/rotor subassembly 140, with rotor 142 on one side of the wall(s) and PCB stator on the other side. In some examples, the stator chamber 134 and the impeller chamber 133 may be separated by a shared wall (not illustrated), which forms part of both chambers. In some examples, the stator chamber 134 and the impeller chamber 133 are distinct chambers but they are fluidically connected together, for example through apertures in the wall(s) separating them. In other examples, the stator chamber 134 and the impeller chamber 133 are fluidically isolated from one another.

As noted, the PCB stator pump 110 comprises one or more PCB stators 120 and one or more rotors 142. These together form a PCB motor of the pump 100. Each rotor 142 comprises a frame that is to rotate about a rotation axis 145. Each rotor 142 also comprises a series of magnetic portions coupled to the corresponding frame. The magnetic portions may be arranged to circumferentially surround the rotation axis 145, with the magnetic portions located in a plane perpendicular to the rotation axis 145. The PCB stator 120 is configured to generate magnetic fields that magnetically interact with the magnetic portions of the corresponding rotor 142 to drive rotation of the rotor 142 about the rotation axis 145. The magnetic portions may comprise permanent magnets and/or magnetically attractable (e.g., ferromagnetic) materials (e.g., iron, steel, etc.) which are capable of interacting with (e.g., being attracted or repelled by) the generated magnetic fields. In some examples, the magnetic portions comprise multiple permanent magnets which are distributed circumferentially around the axis 145 and arranged with alternating polarities.

Each rotor 142 is part of the impeller/rotor subassembly 140, which also includes an impeller 141. The rotor 142 is physically coupled to the impeller 141 such that rotation of the rotor 142 causes rotation of the impeller 141. Thus, the rotation axis 145 is shared in common by the rotor(s) 142 and impeller 141, and it may also be referred to herein as a rotation axis 145 of the impeller rotor subassembly 140. The impeller/rotor subassembly 140 is rotatably coupled to the housing 110, for example by bearings (not illustrated).

In some examples, the rotor(s) 142 is(are) an integral part of the impeller 141. More specifically, in some examples the frame of a rotor 142 may be integrally coupled to the impeller 141, meaning they are part of the same monolithic (unitary) body. For example, the impeller 141 may comprise a body with blades coupled to and extending from the body, and the frame of a rotor 142 may be formed by an axial end portion of the body of the impeller 141, in which case the magnets of the rotor 142 may be coupled to the axial end portion of the body of the impeller 141. In examples where two rotors 142 are present, the frame of one rotor 142 may be integrated into one axial end portion of the impeller 141 while the frame of the other rotor may be integrated into the opposite axial end portion of the impeller 141.

In other examples, the rotor(s) 142 is (or are) formed as a wholly distinct part(s) from the impeller 141 and these are coupled together so as to rotate together about a common rotation axis 145. In some of these examples, a rotor 142 may be coupled directly to the impeller 141, such as by welding, brazing, heat staking, mechanical fasteners, adhesives, or other joining or fastening techniques. In other examples, a rotor 142 is indirectly coupled to the impeller 141; for example, the impeller/rotor subassembly may further comprise a shaft to which both the rotor 142 and impeller 141 are coupled. In examples where a shaft is used to couple the rotor 142 to the impeller 141, because both the impeller 141 and the rotor 142 are disposed within the same impeller chamber 133, the shaft does not need to pierce through a wall of the impeller chamber 133, and thus the difficulties described above related to such piercing can be avoided.

The impeller 141 may be formed from a plastic, a metal, or any other material that can be formed into the desired shape by modeling, casting, 3D printing, machining or any other fabrication technique. In examples in which a rotor 142 is integrated into the impeller 141, the body of the impeller 141 is formed, which results in the formation of the frame of the rotor 142 as part of the body of the impeller 141, and then the magnetic portions (e.g., permanent magnets) may be attached to the frame (i.e., to the body of impeller 141) using adhesives (e.g., epoxy), mechanical fasteners, press fitting, and/or any other fastening technique. In examples in which the rotor 142 is distinct from the impeller, 141, the frame of rotor 142 may be formed by modeling, casting, 3D printing, machining or any other suitable fabrication technique.

Each PCB stator 120 is formed from a PCB which includes a PCB substrate with electrical circuitry formed in and/or on the PCB substrate. The PCB substrate may include laminated layers of insulating material, which may be made from any PCB substrate material, such as FR-4 (a National Electrical Manufacturers Association (NEMA) grade designation for a certain glass-reinforced epoxy laminate material). The electrical circuitry may include internal circuitry inside the PCB substrate, which may include metal (e.g., copper) traces extending in various patterns formed in one more layers inside the PCB substrate. The electrical circuitry may also include discrete electrical components, such as resistors, capacitors, inductors, etc., mounted to a surface of the PCB substrate.

The electrical circuitry of the PCB stator 120 is configured to receive electrical driving signals and, in response, generate magnetic fields that are configured to drive rotation of the rotor 142. Each metal trace through which electrical current flows generates a particular magnetic field, the nature of which depends on the pattern traced out by the metal trace, as well as the direction the current flows therethrough. When current flows through multiple traces simultaneously the magnetic fields generated by these traces combine to form the overall magnetic field generated by the PCB stator 120, with the nature of the overall magnetic field depending on which metal traces current flows through and the directions such current flows. Thus, the overall magnetic field generated by the PCB stator 120 can be varied by selectively supplying electrical current through different portions of the electrical circuitry at different timings and/or in different directions. The driving signals may be controlled to produce a magnetic field that will interact with the permanent magnets to urge the rotor 142 to rotate. As the rotor rotates 142, the positions of the magnetic portions change and therefore the electrical driving signals may periodically be updated, based on the present orientation of the rotor 142, to alter the generated magnetic field such that it continues to urge rotation of the rotor 142 in view of the changed positions of the magnetic portions.

In some examples, PCB stator 120 may be configured to be submersible in liquid coolant 101 without damage to or interruption in operation of the PCB stator 120. This may be particularly useful in those examples where the stator chamber 134 is part of the impeller chamber 133 or where the stator chamber 134 is distinct from, but fluidically coupled with, the impeller chamber 133, as in such examples the liquid 101 will come into contact with the PCB stator 120. In some examples, the internal circuitry of the PCB stator 120 may be shielded from the liquid 101 by the surrounding laminate layers. In some examples, external circuitry on the surface of the PCB stator 120 may be covered with an epoxy or other protective coating to prevent contact with the liquid 101.

In some examples, a single PCB stator 120 may drive multiple rotors 142 simultaneously. For example, one rotor 142 may be disposed on one side of the PCB stator 120 and another rotor 142 on an opposite side of the PCB stator 120, and the magnetic fields generated by the PCB stator 120 may drive simultaneous rotation of both rotors 142.

The electrical driving signals may be received via an electrical cable 126 coupled to the PCB stator 120. This electrical cable 126 may, in turn, be coupled to control circuitry 125, which generates the electrical driving signals for the PCB stator 120. The control circuitry 125 may comprise a microcontroller or other integrated circuit, as well as other discrete active electrical components (e.g., transistors) or passive electrical components (e.g., resistors, inductors, etc.). The control circuitry 125 may also include sensors, such as temperature sensors, electrical power usage sensors, moisture sensors (e.g., for leak detection), magnetic field (e.g., Hall effect) sensors, or other sensors. The control circuitry 125 may also include power delivery components, such as transistors or other switches (e.g., relays), capacitors, diodes, etc. In some examples, the control circuitry 125 may include communications components for communicating with outside devices such as a system controller, baseboard management controller (BMC), rack controller, etc., for example via cables and/or wirelessly (via, e.g., Bluetooth, WiFi, etc.). The control circuitry 125 may be coupled to an outside power source and/or an outside controller via wires or cables (not illustrated) to receive power for its operations, including power for generating the electrical drive signals supplied to the PCB stator 120.

In some examples, the control circuitry 125 may be part of the PCB stator pump 100. In some of these examples, the control circuitry 125 may be formed on the same PCB as the PCB stator 120, while in other examples, the control circuitry 125 may be formed on a different PCB than the PCB stator 120. In particular, in some examples in which the stator chamber 120 is exposed to the liquid 101, the control circuitry 125 may be disposed outside of the impeller chamber 133 and stator chamber 134 so as to avoid liquid 101 reaching, and possibly damaging, the control circuitry 125. In other examples in which the stator chamber 134 is isolated from the liquid 101, the control circuitry 125 may be disposed in the stator chamber 134 with that PCB stator 120 (either on the same PCB as the PCB stator 120, or on another PCB housed in the stator chamber 134). In some examples, the control circuitry 125 is not part of the pump 100 at all, and is instead part of some external system.

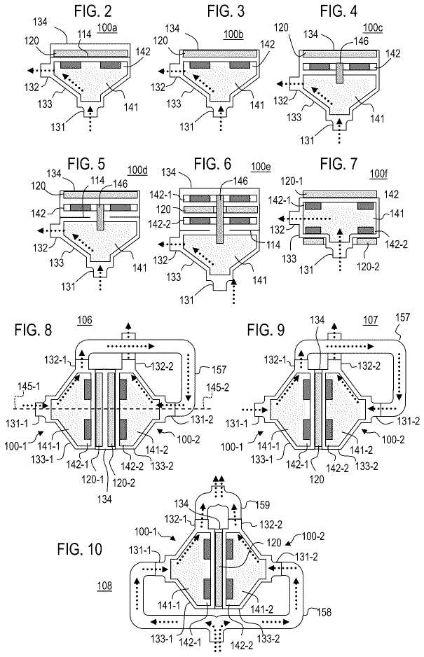

Turning now to FIGS. 2-7, various example configurations of the pump 100 will be described, in the form of pumps 100a to 100f. FIGS. 2-7 are schematic in nature and are not intended to illustrate specific shapes, dimensions, or other structural details. However, FIGS. 2-7 do illustrates some positional relationships between the illustrated parts. Pumps 100a to 100f are all instances of the pump 100 and thus each includes components of the pump 100 already described above, and therefore duplicative description of these components is omitted. The pumps 100a to 100f differ from one another merely in how some of the components are positioned or configured, or in the number of components that are included, as will be described. The pumps 100a-100f are just some of the possible configurations of pump 100, and pump 100 is not limited to pumps 100a-100f.

FIG. 2 depicts pump 100a, which is a first configuration of pump 100. In this configuration, there is one rotor 142, which is part of the impeller 141, and both of these are disposed in the impeller chamber 133. In addition, there is one stator 120, which is housed in a stator chamber 134, which is fluidically isolated from the impeller chamber 133 by a shared wall 114, which is part of both impeller chamber 133 and stator chamber 134. In some examples, pump 100a could be constructed by: forming a partial impeller chamber which comprises the impeller chamber 133 without the shared wall 114; inserting impeller 141 (with rotor 142) into the partial impeller chamber; forming impeller chamber 133 by joining wall 114 to the partial impeller chamber (e.g., by ultrasonic welding, adhesive, or any other liquid-tight joining technique), thus covering the opening and sealing the chamber 133 liquid tight (except for the openings in inlet 131 and outlet 132); and coupling stator 120 and the remaining portions of the stator chamber 134 to the impeller chamber 133. In this configuration, the stator 120 is not exposed to the liquid 101. Thus, the stator chamber 134 does not necessarily need to be liquid tight. In a variation of this configuration (not illustrated), the stator chamber 134 may be omitted and the stator 120 may be attached to the wall 114 and exposed to an external environment. In another variation of this configuration (not illustrated), the shared wall 114 may have holes that fluidically connect the impeller chamber 133 to the stator chamber 134, in which case the stator 120 may be exposed to liquid 101, which may assist in cooling stator 120. In this variation, the stator chamber 134 may be sealed liquid tight to avoid leakage.

FIG. 3 depicts pump 100b, which is a second configuration of pump 100. In this configuration, there is one rotor 142, which is part of the impeller 141, both of which are disposed in the impeller chamber 133. In addition, there is one stator 120, which is housed in a stator chamber 134, which is part of the impeller chamber 133. In other words, in this example, the stator chamber 134 constitutes part of the impeller chamber 133, and therefore the stator 120 can be said to be disposed in impeller chamber 133. In some examples, pump 100b could be constructed by: forming two separate parts of impeller chamber 133, one comprising a partial impeller chamber and one comprising a partial stator chamber 134; inserting impeller 141 (with rotor 142) into the partial impeller chamber; coupling stator 120 to the partial stator chamber; and joining the partial impeller chamber and the partial stator chamber together to form the impeller chamber 133 (with the stator chamber 134 as a part thereof) around the impeller 141, rotor 142, and stator 120. In this configuration, stator 120 in exposed to liquid 101.

FIG. 4 depicts pump 100c, which is a third configuration of pump 100. This configuration is similar to the second configuration (pump 100b) described above except that in the third configuration the rotor 142 is separate and distinct from the impeller 141. Thus, the rotor 142 and impeller 141 may be coupled together, for example, by a shaft 146, one or more fasteners (not illustrated), welding, adhesives, or any other joining or fastening technique. In a variation on the third configuration (not illustrated), instead of the stator chamber 134 being part of the impeller chamber 133, the stator chamber 134 in which stator 120 is housed may be separate and distinct from the impeller chamber 133 (similar to the stator chamber 134 in FIG. 2), with a shared wall separating the chambers 133 and 134.

FIG. 5 depicts pump 100d, which is a fourth configuration of pump 100. This configuration is similar to the third configuration (pump 100c) described above except that in the fourth configuration the stator chamber 134 is separate and distinct from the impeller chamber 133, and both the rotor 142 and the stator 120 are disposed in the stator chamber 134. In this configuration, the stator chamber 134 is fluidically connected to the impeller chamber 133 by one or more holes, including a hole through which a shaft 146 can extend to couple the rotor 142 to the impeller 141. In this configuration, stator 120 is exposed to liquid 101, and thus stator chamber 134 may be sealed to impeller chamber 133 such that the combined chambers 133 and 134 are liquid tight (excluding inlet 131 and outlet 132).

FIG. 6 depicts pump 100e, which is a fifth configuration of pump 100. This configuration is similar to the fourth configuration (pump 100d) described above except that in the fifth configuration there are two rotors 142-1 and 142-2, which are disposed on opposite axial sides of the stator 120. The rotors 142-1 and 142-2 are both coupled to the same shaft 146, which is in turn coupled to impeller 141 via an opening in the wall 114, so that they all rotate together as a unit. Shaft 146 extends through a hole in stator 120, but is not coupled thereto. Stator 120 is coupled to stator chamber 134. In this configuration, the stator 120 drives rotation of both rotors 142-1 and 142-2 simultaneously. In yet another variation, additional rotors 142 and stators 120 may be added, with stators 120 interleaved in between the rotors 142 and the rotors 142 coupled to the same shaft 146 (e.g., three rotors 142 with two stators 120 interleaved therebetween; four rotors 142 with three stators 120 interleaved therebetween, etc.).

FIG. 7 depicts pump 100f, which is a sixth configuration of pump 100. In this configuration, there are two rotors 142-1 and 142-2 and two stators 120-1 and 120-2. The two rotors 141-1 and 141-2 are both part of the impeller 141, with one rotor 141-1 formed on a first axial end of the impeller 141 and the other rotor 141-2 formed on a second axial end of the impeller 141. One of the stators 120-1 is positioned at a first axial end of the impeller chamber 133, axially adjacent rotor 141-1, and the other stator 120-2 is positioned at a second axial end of the impeller chamber 133, axially adjacent rotor 141-2. In this configuration, no stator chambers 134 are present. However, in a variation on this configuration (not illustrated), one or both stators 120 may be housed in stator chambers 134 which are coupled to opposite ends of the impeller chamber 133, with the stator chambers 134 fluidically isolated from the impeller chamber in a similar fashion as in FIG. 2. In another variation, one or both stators 120-1 and 120-2 may be housed in stators chambers 134 as in the previous variation, but there may be holes in the walls between the impeller chamber 133 and the stator chambers 134, thus fluidically connecting them together. In yet another variation, one or both stators 120-1 and 120-2 may be housed in the impeller chamber 133 (i.e., in stator chambers 134 that are joined with the impeller chamber 133). In yet another variation, one or both rotors 142-1 and 142-2 may be separate and distinct from the impeller 141 and may be coupled thereto, e.g., by a shaft, fastener, or other mechanism.

It should be understood that the configurations shown in FIGS. 2-7 are not exhaustive of the configurations of the pump 100. Configurations of the pump 100 may include, among others, variations on the configurations shown and described above, which may include combinations of aspects from any of the configurations described above, in any permutation without limitation, except for any logically contradictory or physically impossible combinations.

Turning to FIGS. 8-10, example multi-stage pump units 106, 107, and 108 (pump units 106, 107, and 108) will be described. These multi-stage pump units 106, 107, and 108 each comprise at least two instances of the pump 100 joined together to form a multi-stage pump unit with multiple (at least two) compressor stages. These pump units 106, 107, or 108 may be similar in function to two separate pumps 100 which are coupled in series or in parallel, but may differ from this in that in the pump unit the pumps are packaged together as one device or module, which can allow for a smaller overall package than two distinct pumps, as well as possibly providing other benefits. For example, as will be described below, in some cases certain parts can be shared between the two pumps, reducing costs and size.

FIG. 8 illustrates a first pump unit 106. This pump unit 106 comprises two pumps 100-1 and 100-2 coupled together with their respective rotation axes 145-1 and 145-2 aligned (coaxial), and with the pumps 100-1 and 100-2 oriented in opposite directions (e.g., the inlet 131-1 of pump 100-1 faces in one direction and the inlet 131-2 of pump 100-2 faces in an opposite direction). Pump 100-1 comprises a fluid chamber 133-1 housing an impeller 141-1 and rotor 142-1. Similarly, pump 100-2 comprises a fluid chamber 133-2 housing an impeller 141-2 and rotor 142-2. The pumps 100-1 and 100-2 also comprise stators 120-1 and 120-2, respectively, which are disposed between the impeller chambers 133-1 and 133-2 in a shared stator chamber 134. The outlet 132-1 is fluidically coupled to inlet 131-2 via liquid line 157, thus connecting pumps 100-1 and 100-2 in series. Thus liquid flows from inlet 131-1 through impeller chamber 133-1, through outlet 132-1, through liquid line 157, through inlet 131-2, through impeller chamber 133-2, and out outlet 132-2. This series arrangement can allow for an increase in the pressure that the pump unit 106 can generate relative to what either pump 100-1 and 100-2 could generate alone.

In some examples, pumps 100-1 and 100-2 are not necessarily identical. For instance, the impeller 141-1 may have a different size and/or shape than the impeller 141-2. The ability to have differently configured impellers 141-1 and 141-2 can allow for the efficiency of the pump unit 106 to be increased. In addition, stators 120-1 and 120-2 can, if desired, drive the rotors 142-1 and 142-2 independently, thus allowing, for example, the impellers 141-1 and 141-2 to rotate at different speeds and/or with different torques applied thereto. This may allow for further increases in efficiency of the pump unit 106.

FIG. 9 illustrates a second pump unit 107. This pump unit 107 is similar to the pump unit 106 except that the pump unit 107 comprises one stator 120, which is shared among both pumps 100-1 and 100-2. That is, the stator 120 can simultaneously drive rotation of both rotors 142-1 and 142-2. This can allow for cost savings and a reduction in size relative to the pump unit 106. However, it may forgo the ability to independently drive the rotors 142-1 and 142-2.

FIG. 10 illustrates a third pump unit 108. This pump unit 108 is similar to the pump unit 107 except that in the pump unit 108 the pumps 100-1 and 100-2 are fluidically connected in parallel, rather than in series. That is, inlets 131-1 and 131-2 are both coupled to the same liquid source via manifold 158, and the outlets 132-1 and 132-2 are both coupled to the same liquid output via manifold 159. Thus, liquid 101 input to manifold 158 splits into two flows, one of which flows through pump 100-1 and the other of which flows through pump 100-2, before being recombined by manifold 159 back into one flow. This parallel arrangement can allow for an increase in the flow rate that the pump unit 108 can generate relative to what either pump 100-1 and 100-2 could generate alone.

FIGS. 8-10 illustrate a few ways in which multi-stage pump units could be formed by combining two of the pumps 100 in a package, but these are examples and not exhaustive. For instance, although the pumps 100-1 and 100-2 in pump units 106, 107, and 108 are shown in the configuration of pump 100a from FIG. 2, the pumps 100-1 and 100-2 could have any of the configurations disclosed herein. As another example, a pump unit could be formed which has two rotors 120 similar to pump unit 106 but with the pumps 100-1 and 100-2 connected in parallel, rather than in series. Furthermore, although the pump units 106-108 are shown with each having two pumps 100-1 and 100-2, other pump units could be formed which comprise more than two pumps 100 each. For instance, a pump unit could include four pumps 100, with the pumps arranged in two pairs, each of the pumps of a pair connected in series, and each of the pairs connected in parallel.

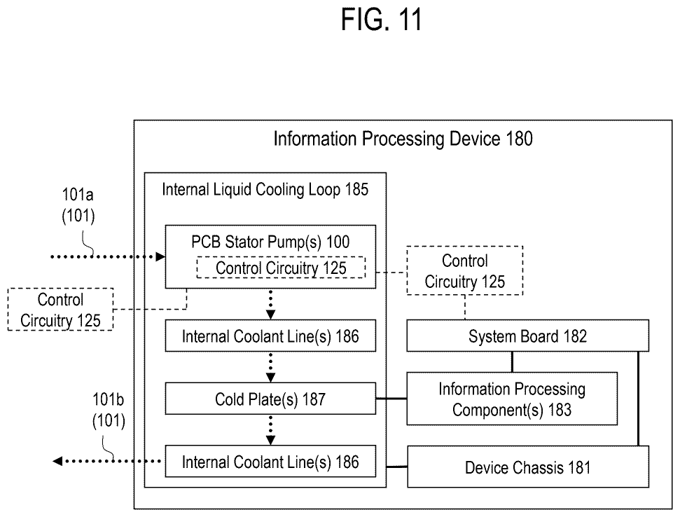

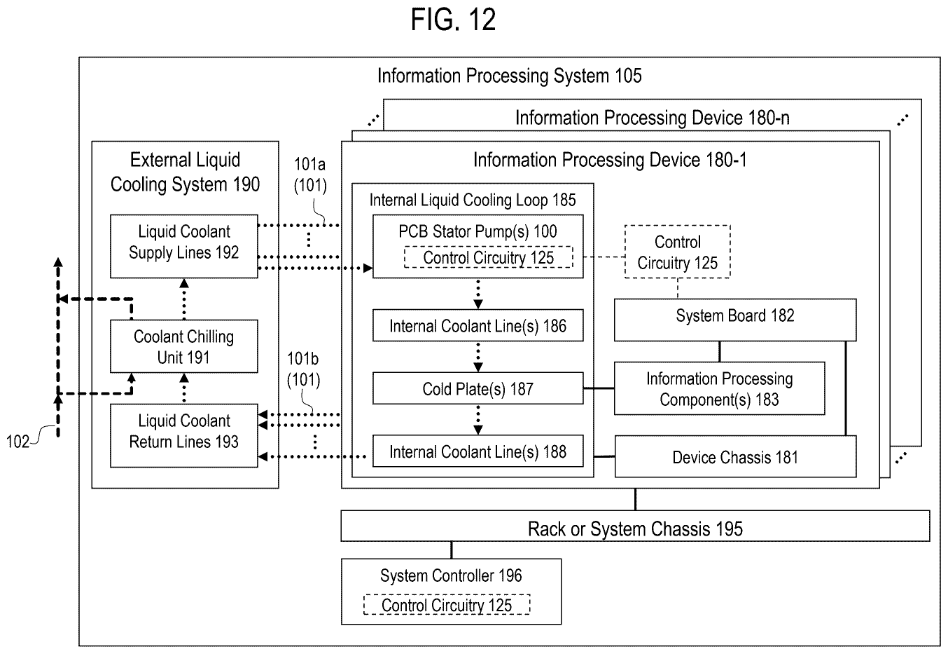

The PCB stator pump 100, or pump units formed therefrom, can be used in various applications, and in particular may be well suited for use in liquid cooling of information processing devices or systems. In some examples, the PCB stator pump 100, or pump units formed therefrom, can have a very small form factor, which allows it to be deployed within the limited space constraints often encountered in liquid cooling information processing devices or systems. Specifically, the small form factor of the PCB stator pump 100, or pump units formed therefrom, can make it well suited for deployment within the chassis of an information processing device, where space is highly limited. FIG. 11 illustrates one example information processing device 180 in which a PCB stator pump 100 (or a pump unit formed therefrom) may be deployed. FIG. 12 illustrates one example information processing system 105 in which pump 100 (or a pump unit formed therefrom) may be deployed. These will be described in more detail below. Note that “information processing device” refers to an electronic device comprising a system board with a processor configured to perform information processing functions, such as an individual server or networking device, whereas “information processing system” refers to a larger system in which one or more such information processing devices may be deployed. For example, a high-performance compute (HPC) system may comprise multiple individual server trays/blades that work together in a coordinated fashion, and in such a context each individual server tray/blade may be referred to as an information processing device while the HPC system as a whole may be referred to as an information processing system. As another example, multiple rack-mountable servers may be mounted to a rack, and in such a context each individual server may be referred to as an information processing device while the rack and the multiple servers mounted thereto may be referred to collectively as an information processing system.

FIG. 11 illustrates an information processing device 180, which may be, for example, a server (e.g., a rack-mountable server, a server tray/blade of an HPC system or blade system, a desktop server, a hyperconverged infrastructure device, a data storage appliance, etc.), a networking device (e.g., network switch, network gateway, etc.), or other information processing device. As shown in FIG. 11, the information processing device 180 comprises a device chassis 181 (also “chassis 181), a system board 182 supported by the chassis 181, information processing components 183 electrically connected to the system board 182, and an internal liquid cooling loop 185 disposed in and supported by the device chassis 181.

The chassis 181 comprises walls, panels, and/or other support structures which support and/or house the other components. These may include a base, side walls, front panel, rear panel, and/or top cover/lid. The chassis 181 may also include cages or bays which receive components, such as drive cages, power supply unit cages, etc. The chassis 181 may also provide EMI shielding functions.

The system board 182 may comprise a motherboard, host-processor module (HPM), or similar printed circuit assemblies which comprise electrical circuitry and logic configured to control operations of the device 180. In particular, the system board 182 comprises at least a socket to which a processor (e.g., a central processing unit (CPU), system on chip (SoC), etc.) is mounted or mountable. System board 182 may also include any or all of: power regulation circuitry (e.g. voltage regulation modules (VRMs)), memory sockets to receive memory modules, connectors to mate with cables or pluggable modules, and control, management, and/or security circuitry (e.g., a baseboard management controller (BMC), a complex programmable logic device (CPLD), etc.).

The information processing components 183 may include the aforementioned processor which is mounted to a processor socket of the system board 182. The information processing components 183 may also include other components which participate in performing information processing functions of the device 180, such as a graphics processing unit (GPU), storage devices (e.g., solid state drives (SSDs)), memory modules (e.g., dual-inline memory modules (DIMMs)), network interface cards (NICs), storage array controllers or host-bus adapters (HBAs), pluggable optical transceivers, etc. Some of these information processing components 183 may be mounted and electrically connected directly to the system board 182 via sockets of the system board 182. Others of the information processing components 183 may be indirectly electrically connected to the system board 182 via cables.

Internal liquid cooling loop 185 comprises liquid cooling infrastructure arranged to cool one or more of the information processing components 183. The internal liquid cooling loop 185 is fluidically couplable to an external liquid cooling system (not illustrated) which supplies liquid coolant 101 thereto. More specifically, a flow of the liquid coolant 101 which is cool (denoted 101a in FIG. 11) is supplied from the external liquid cooling system to the internal liquid cooling loop 185, the liquid 101 is circulated through the internal liquid cooling loop 185 wherein the liquid 101 absorbs heat from one or more of the information processing devices 183, and a flow of the now-heated liquid 101 (denoted 101b in FIG. 11) is then returned from the internal liquid cooling loop 185 to the external liquid cooling system, which cools the liquid 101 and recirculates it back to the internal liquid cooling loop 185.

The liquid cooling infrastructure of the internal liquid cooling loop 185 includes one or more instances of the PCB stator pumps 100 arranged locally to the information processing device 180, meaning disposed within the device chassis 181 or disposed exterior to but immediately adjacent the chassis 181. The PCB stator pump(s) 100 are configured to drive circulation of the liquid 101 through the internal liquid cooling loop 185.

The liquid cooling infrastructure of the internal liquid cooling loop 185 further includes one or more cold plates 187, which are devices configured to thermally couple an information processing component 183 to the liquid 101, thereby allowing heat to flow from the component 183 into the liquid 101, cooling the component 183. For example, the cold plate 187 may comprise a thermally conductive body comprising a first surface configured to thermally coupe with the component 183 by direct contact or by mutual contact with an intermediary, such as a thermal interface material (TIM)), and a second surface configured to thermally couple with the liquid 101 by direct contact or by mutual contact with an intermediary, such that a conductive heat transfer path is formed from the component 183 to the liquid 101 via the cold plate 187. In some examples, the second surface of the cold plate 187 is an internal surface defining a conduit through which the liquid 101 passes with the liquid 101 directly contacting the second surface. In other examples, the liquid 101 may flow through a conductive tube (e.g., copper tube) which is in contact with the second surface of the cold plate 187.

The liquid cooling infrastructure of the internal liquid cooling loop 185 further includes internal coolant lines 186 which fluidically couple the other parts of the liquid cooling loop 185 together. These internal coolant lines 186 may include one or more individual coolant lines, such as tubes or pipes, and/or one or more manifolds which distribute one input into multiple outputs or combine multiple inputs into one output.

In FIG. 11, the flow path of the liquid 101 shown with dotted-line arrows suggests that the pump(s) 100 are upstream of the cold plates 187, with internal coolant line(s) 186 connected therebetween such that an outlet 132 of a given pump 100 is fluidically coupled with a cold plate 187. But this is merely one example to schematically show a flow of liquid 101 through internal liquid cooling loop 185, and it should be understood that the components of the internal liquid cooling loop 185 could be arranged in any order or pattern desired, based on the needs of a particular device 180. For instance, the following is a non-exhaustive and non-limiting list of examples of configurations that the internal liquid cooling loop 185 could have: a single pump 100 is provided and it is disposed upstream of all the cold plate(s) 187; a single pump 100 is provided and it is disposed downstream of all the cold plate(s) 187; a single pump 100 is provided and it is disposed between two or more cold plate(s) 187; multiple pumps 100 are provided and all are upstream of all the cold plate(s) 187; multiple pumps 100 are provided and all are downstream of all the cold plate(s) 187; multiple pumps 100 are provided and some (or all) are in between two or more of the cold plates 187; multiple pumps 100 are provided and some are upstream of all the cold plate(s) 187 and others are downstream of all the cold plates 187. Furthermore, the locations, numbers, and types of internal coolant line(s) 186 are not limited and can be arranged as desired to fit within the needs of a given device 180. For instance, one or multiple pumps 100 could be coupled directly to the external cooling system in some examples, while in other examples internal coolant lines 186 could be disposed between the pump(s) 100 and the external cooling system. As another example, one or multiple pumps 100 could be coupled directly to cold plate(s) 187 in some examples, while in other examples internal coolant lines 186 could be disposed between the pump(s) 100 and the cold plates 187.

As noted, in some examples, multiple pumps 100 may be provided in internal liquid cooling loop 185. This can be done to ensure redundancy in case one pump 100 fails, and/or to achieve certain desired flow characteristics that might otherwise be difficult (or impossible) to achieve with just one pump 100. For instance, in some examples multiple pumps 100 may be arranged in series with one another to allow the pressure of the liquid 101 in the loop 185 to be increased. For example, if a single pump can generate a pressure differential of X at a given flow rate, then N pumps in series can generate a pressure differential of about N·X (neglecting various losses) at the same flow rate. In some examples, multiple pumps 100 may be arranged in parallel with one another to allow the flow rate of the liquid 101 in the loop 185 to be increased. For example, if a single pump can generate a flow rate of Y at a given pressure, then N pumps in parallel can generate a flow rate of about N·Y (neglecting various losses) at that same pressure. In other examples, multiple pumps 100 may be arranged in parallel and in series, such as by providing multiple groups of pumps 100, wherein the pumps 100 within a same group are arranged in series relative to one another and each group is arranged in parallel relative to the other groups. This may allow both pressure and flow rate to be increased. In some examples, some of the pumps 100 could be provided as part of an integrated pump unit, such as one of the pump units 106, 107, or 108.

In some examples, the control circuitry 125 which controls the pump 100 may be part of the pump 100. In other examples, the control circuitry 125 is internal to the information processing device 180 but external to the pump 100. For instance, the control circuitry 125 may be mounted to, or part of, the system board 182, such as a BMC or other controller, or the control circuitry 125 may be part of a separate module which may be removably installed in device chassis 181. In other examples, control circuitry 125 is external to information processing device 180. In some examples in which information processing device 180 comprises multiple pumps 100, each pump 100 has its own corresponding instance of control circuitry 125 (whether internal or external to pump 100) that controls operations of that pump 100. Accordingly, each pump 100 may be individually controllable (e.g., via a respective control circuitry 125) to individually adjust flow rates of the liquid 101. In some examples in which information processing device 180 comprises multiple pumps 100, multiple pumps 100 may be controlled by a shared instance of control circuitry 125 (whether internal or external to device 180).

FIG. 12 illustrates an information processing system 105. The information processing system 105 comprises multiple information processing devices, which may include multiple instances of information processing device 180, labeled 180-1 to 180-n in FIG. 12.

The information processing system 105 may further comprise a rack or system chassis 195 configured to receive and support the information processing devices 180. In some examples, the rack or system chassis 195 may comprise a standard server rack, configured to receive multiple rack mountable servers or other equipment. In other examples, the rack or system chassis 195 may include a system chassis configured to house multiple pluggable trays or blade servers, such as an HPC system chassis or blade system chassis. The information processing system 105 may further include a system controller 196, which orchestrates and/or controls certain operations of the information processing devices 180 and/or the system 105 as a whole.

In some examples, the processing system 105 may also include an external liquid cooling system 190. The external liquid cooling system 190 is “external” in the sense that it is external to the information processing devices 180, in contrast to their individual internal liquid cooling loops 185. In some examples, external liquid cooling system 190 is disposed in the rack or system chassis 195, while in other examples the external liquid cooling system 190 may be disposed external to the rack or system chassis 195, such as in a coolant distribution unit (CDU). The external liquid cooling system 190 is configured to supply flows 101a of cool liquid coolant 101 to the information processing devices 180 via various liquid coolant supply lines 192, which may include tube, pipes, manifolds and/or various other liquid cooling infrastructure fluidically coupled together and, ultimately, to the internal liquid cooling loops 185 of the devices 180. The external liquid cooling system 190 is also configured receive return flows 101b of warmed liquid coolant 101 from the information processing devices 180 via various liquid coolant return lines 193 which may include tube, pipes, manifolds and/or various other liquid cooling infrastructure fluidically coupled together and, ultimately, to the internal liquid cooling loops 185 of the devices 180. The external liquid cooling system 190 may also include a coolant chilling unit 191, which receives the warmed flows 101b of liquid coolant 101 and removes heat therefrom, thereby generating the cool flows 101a of liquid coolant 101. The coolant chilling unit 191 may include, in some examples, a liquid-to-liquid heat exchanger that receives facility coolant 102 from a facility coolant line and transfers heat from the liquid 101 into the facility coolant 102 (the coolant 102 may remain isolated from the liquid 101, with heat exchange occurring via conduction through the heat exchanger). The facility coolant 102 may circulate through a larger facility (e.g., datacenter) in which the system 105 is deployed, and may remove heat from similar liquid cooling systems of multiple other systems. The facility coolant 102 may ultimately dissipate this heat, returning the facility coolant 102 to a predetermined cool temperature, via a facility cooling system, such as a chiller tower or other systems familiar to those in the art. In other examples, the coolant chilling unit 191 may include, in some examples, a liquid-to-air heat exchanger that receives cool air from the facility (e.g., conditioned air) and transfers heat from liquid 101 into the cool air.

In some examples, external liquid cooling systems 190 may further include one or more pumps (not illustrated), such as pumps in a CDU, which assist in circulating liquid 101 through external liquid cooling systems 190. In such examples, the pumps 100 of the external liquid cooling systems 190 may provide a baseline level of pumping power and the pumps 100 inside the individual information processing devices 180 may supplement this pumping power. In other examples, the pumps 100 inside the devices 180 may allow for external pumps to be omitted from external liquid cooling systems 190 entirely, with the pumps 100 collectively driving circulation of liquid 101 not only through their respective internal liquid cooling loops 185 but also through the external liquid cooling system 190. Whether external pumps are provided or not, the pumps 100 local to the devices 180 may allow for individualized control of the flows of liquid 101 through the various information processing devices 180. In other words, the pumps 100 can individually adjust the flow rates of the liquid coolant through the information processing devices 180. This can allow for more efficient operation, as devices 180 can receive exactly the flow rate of liquid 101 that they need given their current operating conditions.

The control circuitry 125 may be configured to provide this control over the pumps 100 that is individualized at the device 180 level, for example by sensing temperatures or other parameters of certain devices 180 and controlling the pumps 100 of those devices 180 based on the sensed parameters. Thus, the pumps 100 of one information processing device 180 may be controlled to produce one flow rate to meet the needs of that device 180 while the pumps 100 of another information processing device 180 may be controller to produce a different flow rate to meet the different needs of the other device 180. As explained above, in some examples, control circuitry 125 is internal to each pump 100. In some examples control circuitry 125 is external to the pumps 100 and internal to the information processing devices 180. In some examples control circuitry 125 is external to the information processing devices 180. For instance, in some examples, control circuitry 125 may be part of the system controller 196, or some other part of the information processing system 105.

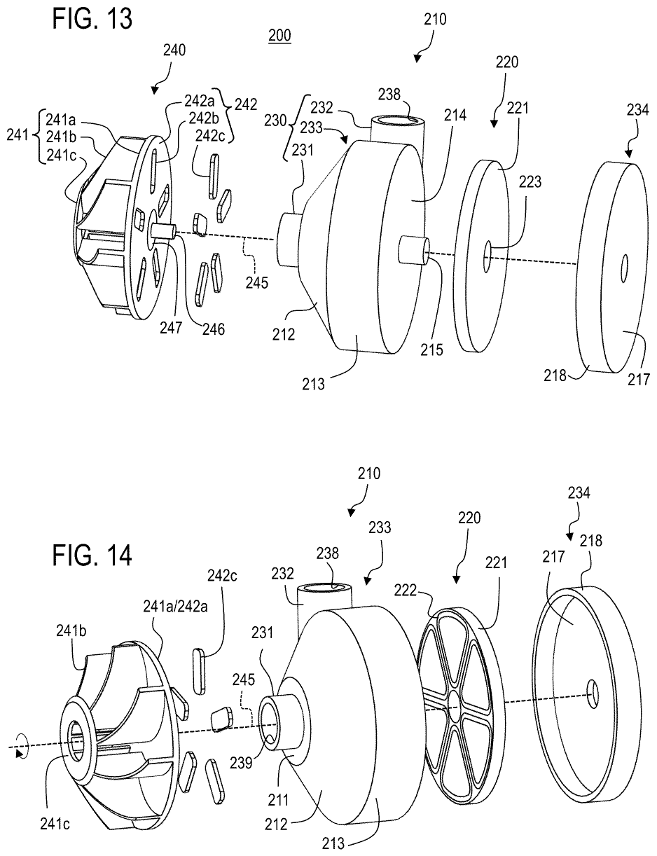

Turning now to FIGS. 13-16, a PCB stator pump 200 (pump 200) will be described. The pump 200 is one implementation example of the pump 100 described above, and thus some components of the pump 200 correspond to (i.e., are implementation examples of) components of the pump 100 already described above. Such corresponding components are referred to herein using the reference numbers having the same last two digits, such as 220 and 120. The pump 200 is but one example of how the pump 100 might be implemented, and thus descriptions and illustrations of structural and other details of pump 200 do not limit the pump 100.

As shown in FIGS. 13 and 14, the pump 200 comprises a housing 210, a PCB stator 220, and an impeller/rotor subassembly 240 that includes an impeller 241 and a rotor 242. As shown in FIG. 13, the housing 210 comprises a liquid conduit 230 and a stator chamber 234, the liquid conduit 230 comprising an inlet 231, an outlet 232, and an impeller chamber 233. The impeller/rotor subassembly 240 is positioned inside the impeller chamber 233 and the rotor 220 is positioned inside the stator chamber 234, as shown in FIG. 16 (note that FIGS. 13 and 14 are exploded views, which is why the impeller/rotor subassembly 240 is shown outside the impeller chamber 233 in those views).

The impeller chamber 233 comprises end walls 211 and 214 perpendicular to rotation axis 245 and peripheral walls 212 and 213 circumferentially surrounding rotation axis 245. Wall 212 may have a shape of a hollow conical section, while wall 213 may have a shape of a hollow cylinder. Impeller chamber 233 encloses a volume 233′, which is visible in FIG. 16, in which impeller/rotor subassembly 240 is housed. Initially, a body comprising walls 211, 212, and 213 may be formed (without wall 214) thus only partially enclosing the volume 223′ with an opening into the volume 223′ at the location where end wall 214 will eventually be positioned. Then, impeller/rotor subassembly 240 may inserted into volume 233′ via this opening. After this, the end wall 214 (e.g., a cover) may be sealed to peripheral wall 213 to close the opening with the subassembly 240 inside the volume 233′.

The impeller chamber 233 may also include a bearing receptacle 215, which protrudes axially from the end wall 214. This bearing receptable 215 may hold a bearing which rotatably couples the impeller/rotor subassembly 240 to the impeller chamber 233. In the illustration, this bearing comprises a shaft 246 received in and fixedly coupled to bearing receptacle 215 and a ball bearing 247 coupled to shaft 246 and to impeller 241. The ball bearing 247 allows impeller 241 to rotate relative to the shaft 246, and thus relative to chamber 233. In other examples, different bearing arrangements could be used—for example, impeller could be coupled fixedly to shaft 246 and shaft 246 may be rotatably coupled to bearing receptable 215, forming a so-called plain bearing. Or in other examples additional bearings (including, but not limited to, ball bearings) could be added, as would be familiar to those of ordinary skill in the art.

As shown in FIGS. 14 and 16, inlet 231 is coupled to end wall 211. As shown in FIG. 16, inlet 231 includes an opening 237 through end wall 211 and an opening 239 opposite from opening 237, with inlet 231 defining a channel between the openings 237 and 239 that fluidically connects the interior volume 233′ of impeller chamber 233 to an external environment.

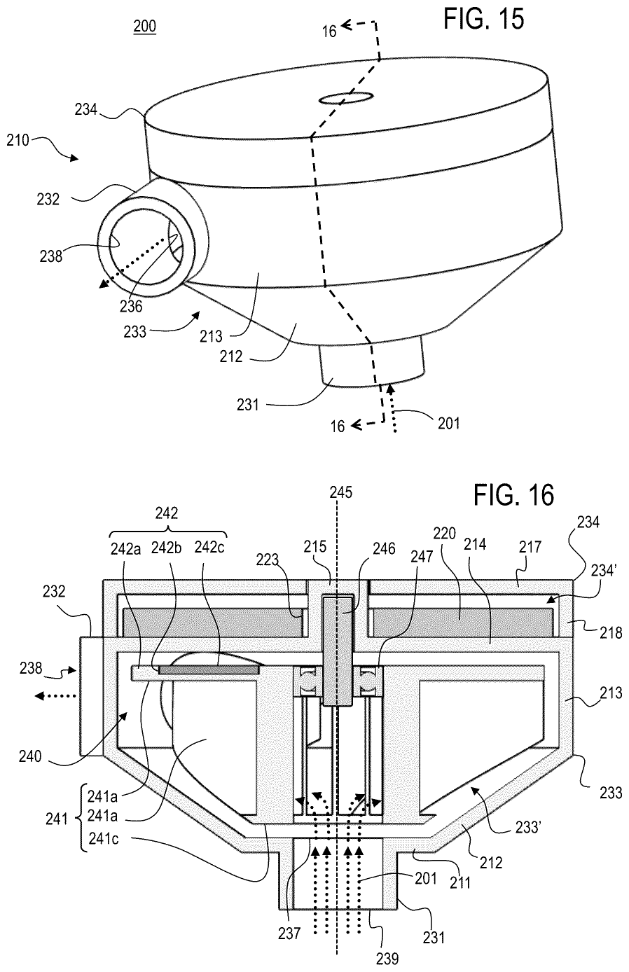

As shown in FIGS. 15 and 16, outlet 232 is coupled to peripheral wall 213. As shown in FIG. 15, outlet 232 includes an opening 236 through wall 213 and an opening 238 opposite from opening 236, with outlet 232 defining a channel between the openings 236 and 238 that fluidically connects the interior volume 233′ of impeller chamber 233 to an external environment.

The liquid conduit 230 encloses a volume and defines a liquid flow path for liquid 201 through that enclosed volume, with the liquid flow traversing from opening 239 of inlet 231, through impeller chamber 133, to opening 238 of outlet 232. The conduit 230 may be liquid tight except for allowing fluid communication into and out of the conduit 230 through the inlet 231 and outlet 232.

Impeller/rotor subassembly comprises the impeller 241 and the rotor 242, at least part of which is formed integrally into the impeller 241. The impeller 241 may comprise a first axial end portion 241a, a second axial end portion 241c, and blades 241b extending between the axial end portions 241a and 241c, as shown in FIGS. 13 and 14. Furthermore, the rotor 242 may comprise a frame 242a and magnets 242c. In this example, the frame 242a of the rotor 242 is part of the axial end portion 241c of the impeller 241. Magnet receptacles 242b may be formed into an axial face of the axial end portion 241c (which is also the axial face of the frame 242a), and the magnets 242c may be disposed therein and attached to the frame 242a via adhesive, friction fit, or any other joining or fastening technique. The rotor 242 and impeller 241 thus rotate together about the rotation axis 245.

As shown in the exploded views of FIGS. 13 and 14, the stator chamber 234 may comprise an end wall 217 perpendicular rotation axis 245 and a peripheral wall circumferentially surrounding axis 245, which are joined together. The stator chamber 234 also comprises end wall 214, which may be shared with the impeller chamber 233. The end wall 214 may initially be formed as part of impeller chamber 233 during its manufacture, as described above, and then may later become part of the stator chamber 234. For example, subsequent to formation of the impeller chamber 233, stator 220 may be assembled onto end wall 214 axially adjacent to rotor 242, a body comprising end wall 217 and peripheral wall 218 may be positioned over stator 220, and then the peripheral wall 218 may be joined to the end wall 214 and/or peripheral wall 213 of impeller chamber 233, for example by ultrasonic welding, adhesive, or any other joining or fastening technique. Thus, the pump 200 utilizes the first configuration shown in FIG. 2 in which the stator chamber 234 is distinct and fluidically isolated from the impeller chamber 233 (e.g., the pump 200 is an implementation example of pump 100a).

The stator 220 may comprise a PCB 221, which may include electrical circuitry 222. The electrical circuitry 222 is illustrated schematically in FIG. 14 as a pattern of exposed electrical traces, but it should be understood that this is not intended to illustrate the actual patterns of the electrical traces. Moreover, in practice some (or all) of the electrical traces may be buried in internal layers of the PCB 221. The PCB 221 may also include an aperture 223, which is to receive the bearing receptable 215 inserted therethrough, as shown in FIG. 16.

The electrical circuitry of the PCB stator 220 is configured to receive electrical driving signals and, in response, generate magnetic fields that are configured to drive rotation of the rotor 242. The electrical driving signals may be received via an electrical cable (not illustrated) coupled to the PCB stator 220. Control circuitry (not illustrated) may be part of the PCB stator pump 200 in some examples, with the control circuitry being disposed either in stator chamber 234 or outside stator chamber 234.

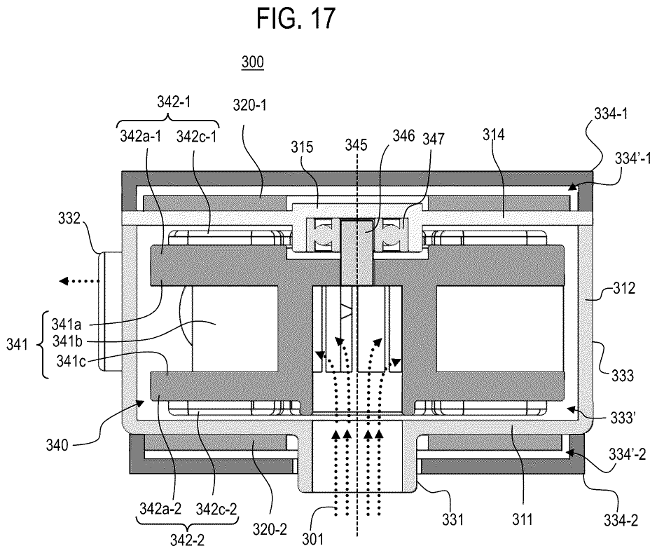

Turning now to FIG. 17, a PCB stator pump 300 (pump 300) will be described. The pump 300 is another implementation example of the pump 100 described above, and thus some components of the pump 300 correspond to (i.e., are implementation examples of) components of the pump 100 already described above. Such corresponding components are referred to herein using the reference numbers having the same last two digits, such as 320 and 120. The pump 300 is but one example of how the pump 100 might be implemented, and thus descriptions and illustrations of structural and other details of pump 300 do not limit the pump 100.

As shown in FIG. 17, the pump 300 comprises an inlet 331, an outlet 332, an impeller chamber 333, an impeller/rotor subassembly 340 disposed in an interior volume 333′ of impeller chamber 333, and stator chambers 334-1 and 334-2 housing PCB stators 320-1 and 320-2, respectively. Liquid 301 can flow into pump 300 via inlet 331, through impeller chamber 333, and out pump 300 via outlet 332.

Pump 300 has a configuration similar to that illustrated in FIG. 7, with pump 300 being an implementation example of the pump 100f. Specifically, in pump 300 there are two rotors 342-1 and 342-2 formed in opposite axial end portions of impeller 341. Rotor 342-1 comprises a frame 342a-1 formed from axial end portion 341a of impeller 341 and magnets 342c-1 coupled to the frame 342a-1. Rotor 342-2 comprises a frame 342a-2 formed from axial end portion 341c of impeller 341 and magnets 342c-2 coupled to the frame 342a-1. Impeller further comprises blades 341b extending between end portions 341a and 341c. The pump 300 further includes two PCB stators 320-1 and 320-2 disposed on opposite axial sides of the impeller chamber 333 axially adjacent to the rotors 342-1 and 342-2. More specifically, the impeller chamber 333 comprises end walls 311 and 314 perpendicular to rotation axis 345 and peripheral wall 312 circumferentially surrounding rotation axis 345, and stator 320-1 disposed on end wall 314 while stator 320-2 is disposed on the end wall 311. Thus, stator 320-1 can drive rotation of rotor 342-1, while stator 320-1 can drive rotation of rotor 342-2. Both rotors 342-1 and 342-2 are coupled to the same rigid body, namely impeller 341, and thus they all rotate together about rotation axis 345.

The impeller chamber 333 may also include a bearing receptacle 315, which protrudes axially from the end wall 314. This bearing receptable 315 may hold a bearing which rotatably couples the impeller/rotor subassembly 340 to the impeller chamber 333. In the illustration, this bearing comprises a ball bearing 347 coupled to bearing receptacle 315 and shaft 346 such that shaft 346 can rotate relative to chamber 333, with the shaft 346 being fixedly coupled to impeller 341. In other examples, different bearing arrangements could be used.

In FIG. 17, two stator chambers 334 are shown, but in some examples, the stator chambers 334 could be omitted and the PCB stators 320-1 and 320-2 could be exposed to an external environment.

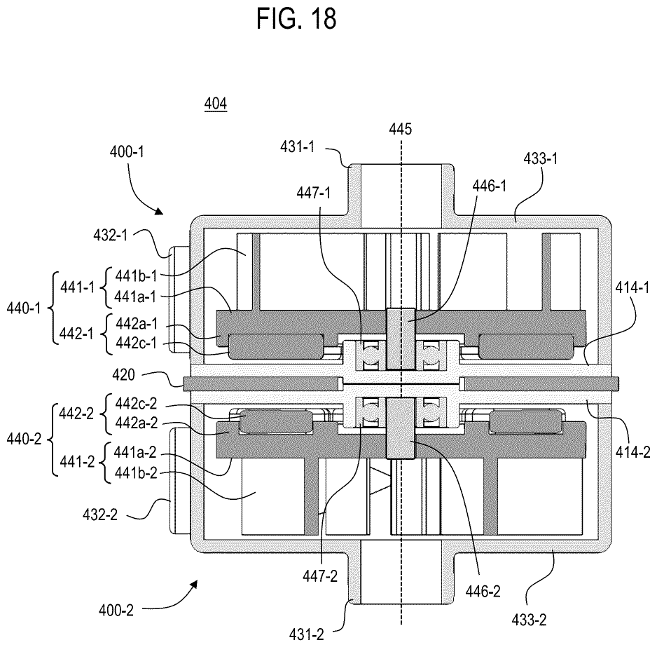

Turning now to FIG. 18, a pump unit 404 comprising two PCB stator pumps 400-1 and 400-2 will be described. The pumps 400-1 and 400-2 are implementations examples of the pump 100 described above, and thus some components of the pumps 400-1 and 400-2 correspond to (i.e., are implementation examples of) components of the pump 100 already described above. Such corresponding components are referred to herein using the reference numbers having the same last two digits, such as 420 and 120. The pumps 400 are but one example of how the pump 100 might be implemented, and thus descriptions and illustrations of structural and other details of pumps 400 do not limit the pump 100.

As shown in FIG. 18, the pump unit 404 comprises two pumps 400-1 and 400-2 that share a single PCB stator 420. Pump 400-1 comprises an inlet 431-1, an outlet 432-1, an impeller chamber 433-1, an impeller/rotor subassembly 440-1 disposed in an interior volume of impeller chamber 433-1, and the stator 420. Pump 400-2 comprises an inlet 431-2, an outlet 432-2, an impeller chamber 433-2, an impeller/rotor subassembly 440-2 disposed in an interior volume of impeller chamber 433-2, and the stator 420, which is shared with the pump 400-1.

The pumps 400-1 and 400-2 are aligned coaxially along rotation axis 445, with inlets 431-1 and 431-2 thereof facing in opposite directions, with rotor 420 in the middle.

Impeller/rotor subassembly 440-1 comprises an impeller 441-1 and rotor 442-1 integrally formed in impeller 441-1. Impeller 441-1 comprises an axial end portion 441a-1 and blades 441b-1. Rotor 442-1 comprises a frame 442a-1 formed from axial end portion 441a-1 of impeller 441-1 and magnets 442c-1 coupled to the frame 442a-1.

Impeller/rotor subassembly 440-2 comprises an impeller 441-2 and rotor 442-2 integrally formed in impeller 441-2. Impeller 441-2 comprises an axial end portion 441a-2 and blades 441b-2. Rotor 442-2 comprises a frame 442a-2 formed from axial end portion 441c-2 of impeller 441-2 and magnets 442c-2 coupled to the frame 442a-2.

PCB stator 420 is disposed axially adjacent the rotor 442-1 on one side of the stator 420 with a wall 414-1 of impeller chamber 433-1 disposed therebetween. PCB stator 420 is also disposed axially adjacent to the rotor 442-2 on an opposite of the stator 420, with a wall 414-2 of impeller chamber 433-1 disposed therebetween. Thus, stator 420 can drive rotation of both impeller/rotor sub-assemblies 440-1 and 440-2.

The impeller chambers 433-1 and 433-2 may each also include a bearing receptacle, which protrudes axially from the end wall 414-1 or 414-2 and which may hold bearing mechanisms to rotatably couple the impeller/rotor sub-assemblies 440-1 and 440-2 to the impeller chambers 433-1 and 433-2, respectively. These bearing mechanisms may comprise shafts 446-1 and 446-2 and ball bearings 447-1 and 447-2, similar to those explained above.

In FIG. 18, no stator chambers is shown, but in some examples, a stator chamber may be disposed between the impeller chambers 433-1 and 433-2 to house the stator 420, with the stator chamber being shared by both pumps 400-1 and 400-2.

Although not illustrated, in some examples, the pumps 400-1 and 400-2 could fluidically be coupled together in series or in parallel, in which case the resulting pump unit 404 would be an example implementation of the pump unit 107 or 108 described above.

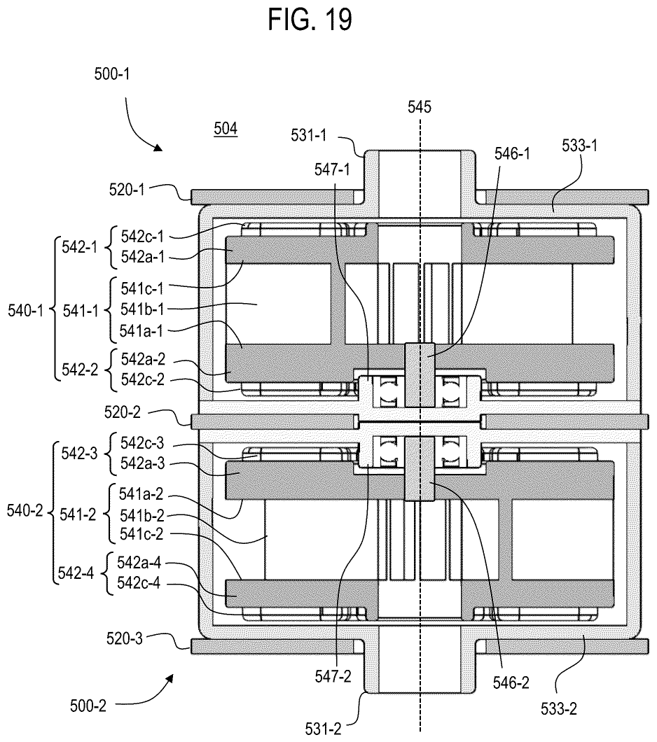

Turning now to FIG. 19, a pump unit 504 comprising two PCB stator pumps 500-1 and 500-2 will be described. The pumps 500-1 and 500-2 are implementations examples of the pump 100 described above, and thus some components of the pumps 500-1 and 500-2 correspond to (i.e., are implementation examples of) components of the pump 100 already described above. Such corresponding components are referred to herein using the reference numbers having the same last two digits, such as 520 and 120. The pumps 500 are but one example of how the pump 100 might be implemented, and thus descriptions and illustrations of structural and other details of pumps 500 do not limit the pump 100.

As shown in FIG. 19, the pump unit 504 comprises two pumps 500-1 and 500-2 that share a single PCB stator 520-2, in addition to having non-shared PCB stators 520-1 and 520-3. Pump 500-1 comprises an inlet 531-1, an outlet (not visible), an impeller chamber 533-1, an impeller/rotor subassembly 540-1 disposed in an interior volume of impeller chamber 533-1, and the stators 520-1 and 520-2. Pump 500-2 comprises an inlet 531-2, an outlet (not visible), an impeller chamber 533-2, an impeller/rotor subassembly 540-2 disposed in an interior volume of impeller chamber 533-2, and the stators 520-2 and 520-3.

The pumps 500-1 and 500-2 are aligned coaxially along rotation axis 545, with inlets 531-1 and 531-2 thereof facing in opposite directions, with stator 520-2 in the middle.

Impeller/rotor subassembly 540-1 comprises an impeller 541-1 and two rotors 542-1 and 542-2 integrally formed in impeller 541-1. Impeller 541-1 comprises an axial end portion 541a-1, an axial end portion 541c-1, and blades 541b-1. Rotor 542-1 comprises a frame 542a-1 formed from axial end portion 541c-1 of impeller 541-1 and magnets 542c-1 coupled to the frame 542a-1. Rotor 542-2 comprises a frame 542a-2 formed from axial end portion 541a-1 of impeller 541-2 and magnets 542c-2 coupled to the frame 542a-2.

Impeller/rotor subassembly 540-2 comprises an impeller 541-2 and two rotors 542-3 and 542-4 integrally formed in impeller 541-2. Impeller 541-2 comprises an axial end portion 541a-2, an axial end portion 541c-2, and blades 541b-2. Rotor 542-3 comprises a frame 542a-3 formed from axial end portion 541a-2 of impeller 541-2 and magnets 542c-3 coupled to the frame 542a-3. Rotor 542-4 comprises a frame 542a-4 formed from axial end portion 541c-2 of impeller 541-2 and magnets 542c-4 coupled to the frame 542a-4.

PCB stator 520-1 is disposed at one end of the impeller chamber 533-1 axially adjacent the rotor 542-1. PCB stator 520-2 is disposed between impeller chambers 533-1 and 533-2 axially adjacent the rotor 542-2 on one side and axially adjacent to the rotor 542-3 on an opposite side. PCB stator 520-3 is disposed at one end of the impeller chamber 533-2 axially adjacent the rotor 542-4. Thus, PCB stator 520-1 can drive rotation of rotor 542-1, PCB stator 520-2 can drive rotation of both rotors 542-2 and 542-3, and PCB stator 520-3 can drive rotation of rotor 542-4.

The impeller chambers 533-1 and 533-2 may each also include a bearing receptacle, which may hold bearing mechanisms to rotatably couple the impeller/rotor sub-assemblies 540-1 and 540-2 to the impeller chambers 533-1 and 533-2, respectively. These bearing mechanisms may comprise shafts 546-1 and 546-2 and ball bearings 547-1 and 547-2, similar to those explained above.

In FIG. 19, no stator chambers is shown, but in some examples, a stator chamber may be disposed between the impeller chambers 533-1 and 533-2 to house the stator 520, with the stator chamber being shared by both pumps 500-1 and 500-2.

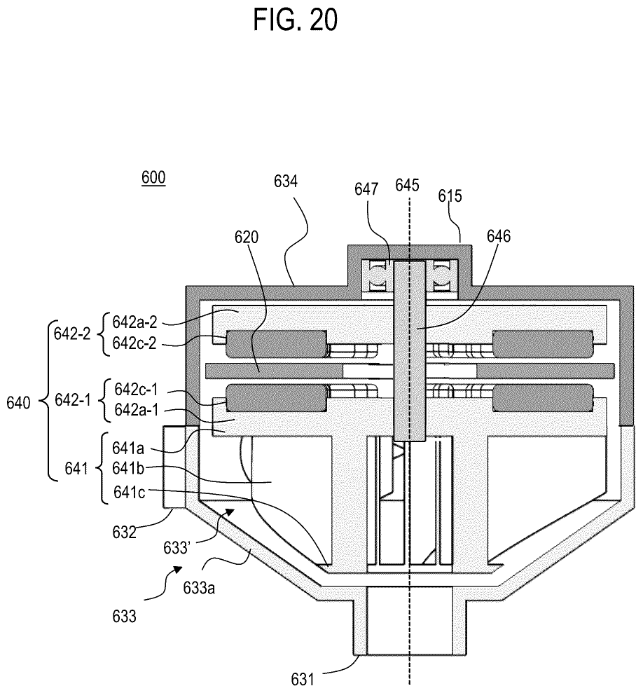

Turning now to FIG. 20, a PCB stator pump 600 (pump 600) will be described. The pump 600 is another implementation example of the pump 100 described above, and thus some component of the pump 600 correspond to (i.e., are implementation examples of) components of the pump 100 already described above. Such corresponding components are referred to herein using the reference numbers having the same last two digits, such as 620 and 120. The pump 600 is but one example of how the pump 100 might be implemented, and thus descriptions and illustrations of structural and other details of pump 600 do not limit the pump 100.

As shown in FIG. 20, the pump 600 comprises an inlet 631, an outlet 632, an impeller chamber 633, an impeller/rotor subassembly 640 disposed in an interior volume 633′ of impeller chamber 633, and a stator chambers 634 housing PCB stator 620.

In pump 600 there are two rotors 642-1 and 642-2, with one integrally formed with impeller 641 and the other formed separately from impeller 641. Impeller comprises end portions 641a and 641c and blades 641b extending between end portions 641a and 641c. Rotor 642-1 comprises a frame 642a-1, which is formed from axial end portion 641a of impeller 641, and magnets 642c-1 coupled to the frame 642a-1. Rotor 642-2 comprises a frame 642a-2, which is distinct from impeller 641, and magnets 642c-2 coupled to the frame 642a-2. Stator 620 sits between, and axially adjacent to, the two rotors 642. The PCB stator 620 is disposed between the rotors 642-1 and 642-2. Thus, stator 620-1 can drive rotation of rotors 642-1 and 642-2. Rotor 642-2 is coupled to a shaft 646, which is in turn coupled to impeller 641, and thus both rotors 641-1 and 641-2 and the impeller 641 all rotate together about rotation axis 645.

In this example, the stator chamber 634 is part of the impeller chamber 633. Specifically, impeller chamber 633 may comprise a first chamber portion 633a and stator chamber 634, which are formed separately and then joined together. Prior to being joined together, impeller/rotor subassembly 640 may be disposed in the interior volume 633', and the first chamber portion 633a and stator chamber 634 may be brought together with the subassembly 640 contained therebetween. The first chamber portion 633a and stator chamber 634 may then be joined in a liquid tight manner, for example by ultrasonic welding or any other suitable joining technique, to complete the formation of the impeller chamber 633.

The impeller chamber 633 may also include a bearing receptacle 615, which protrudes axially from the end wall of the stator chamber 634. This bearing receptable 615 may hold a bearing which rotatably couples the impeller/rotor subassembly 640 to the impeller chamber 633. In the illustration, this bearing comprises a ball bearing 647 coupled to bearing receptacle 615 and to the shaft 646 such that shaft 646 can rotate relative to chamber 633. As noted, the shaft 646 is also fixedly coupled to impeller/rotor subassembly 640, and thus impeller/rotor subassembly 640 rotate along with shaft 646 relative to chamber 633. In other examples, different bearing arrangements could be used.

It is to be understood that both the general description and the detailed description provide examples that are explanatory in nature and are intended to provide an understanding of the present disclosure without limiting the scope of the present disclosure. Various mechanical, compositional, structural, electronic, and operational changes may be made without departing from the scope of this description and the claims. In some instances, well-known circuits, structures, and techniques have not been shown or described in detail in order not to obscure the examples. Like numbers in two or more figures represent the same or similar elements.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Elements and their associated aspects that are described in detail with reference to one example may, whenever practical, be included in other examples in which they are not specifically shown or described. For example, if an element is described in detail with reference to one example and is not described with reference to a second example, the element may nevertheless be claimed as included in the second example.

Unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

Further modifications and alternative examples will be apparent to those of ordinary skill in the art in view of the disclosure herein. For example, the devices and methods may include additional components or steps that were omitted from the diagrams and description for clarity of operation. Accordingly, this description is to be construed as illustrative only and is for the purpose of teaching those skilled in the art the general manner of carrying out the present teachings. It is to be understood that the various examples shown and described herein are to be taken as exemplary. Elements and materials, and arrangements of those elements and materials, may be substituted for those illustrated and described herein, parts and processes may be reversed, and certain features of the present teachings may be utilized independently, all as would be apparent to one skilled in the art after having the benefit of the description herein. Changes may be made in the elements described herein without departing from the scope of the present teachings and following claims.

It is to be understood that the particular examples set forth herein are non-limiting, and modifications to structure, dimensions, materials, and methodologies may be made without departing from the scope of the present teachings.

Other examples in accordance with the present disclosure will be apparent to those skilled in the art from consideration of the specification and practice of the invention disclosed herein. It is intended that the specification and examples be considered as exemplary only, with the following claims being entitled to their fullest breadth, including equivalents, under the applicable law.

What is claimed is:

1. A pump for delivering liquid coolant to cool an information processing device, comprising:
a conduit defining a flow path from an inlet of the conduit to an outlet of the conduit;
an impeller/rotor subassembly comprising an impeller and a rotor disposed in the conduit and rotatable together relative to the conduit about a rotation axis; and
a printed circuit board (PCB) stator positioned axially adjacent to the rotor and oriented perpendicular to the rotation axis and configured to drive rotation of the rotor.

2. The pump of claim 1,
wherein the conduit comprises the inlet, the outlet, and an impeller chamber, and
wherein the impeller chamber houses the impeller and the rotor.

3. The pump of claim 2,
wherein at least a portion of the rotor is integrally formed in the impeller.

4. The pump of claim 3,
wherein the rotor comprises a frame integrally formed in an axial end portion of the impeller and magnets coupled to the frame.

5. The pump of claim 1,
wherein the conduit comprises the inlet, the outlet, an impeller chamber, and a stator chamber fluidically coupled with the impeller chamber,
wherein the impeller chamber houses the impeller, and
wherein the stator chamber houses the PCB stator.

6. The pump of claim 5,
wherein the rotor is housed in the stator chamber and is coupled to the impeller by a shaft that extends through an opening in a shared wall between the stator chamber and the impeller chamber.

7. The pump of claim 5,
wherein the impeller/rotor subassembly further comprises a second rotor disposed axially adjacent to the PCB stator on an opposite side of the PCB stator from the rotor, the second rotor coupled to the rotor and the impeller by a shaft.

8. The pump of claim 1,
wherein the rotor is coupled to, or formed in, a first axial end of the impeller and the impeller/rotor subassembly further comprises a second rotor coupled to, or formed in, a second axial end of the impeller; and
wherein the pump further comprises a second PCB stator disposed axially adjacent the second rotor.

9. The pump of claim 1, further comprising:
a stator chamber housing the PCB stator,
wherein the conduit comprises the inlet, the outlet, and an impeller chamber housing the impeller, and
wherein the stator chamber is fluidically isolated from the impeller chamber.

10. The pump of claim 1,
wherein the PCB stator comprises a PCB with electrical circuitry formed therein, the electrical circuitry configured to, in response to receiving electrical driving signals, generate magnetic fields that cause the rotor to rotate.

11. A multi-stage pump unit comprising:
a first pump according to claim 1; and
a second pump according to claim 1 coupled to and arranged coaxially with the first pump with inlets of the first and second pumps facing in opposite directions,
wherein the first and second pumps are fluidically coupled with one another in series or in parallel.

12. The pump unit of claim 11,
wherein the PCB stator of the first pump comprises a first PCB stator, and the PCB stator of the second pump comprises a second PCB stator, and
wherein the first and second PCB stators are disposed between the conduit of the first pump and the conduit of the second pump.

13. The pump unit of claim 11,
wherein the PCB stator of the first pump comprises a first PCB stator, and the PCB stator of the second pump comprises the first PCB stator,
wherein the first PCB stator is disposed between the conduit of the first pump and the conduit of the second pump.

14. An information processing device, comprising:
a system board;
an information processing component coupled to the system board;
a chassis supporting the system board;
a cold plate thermally coupled to the information processing component; and
the pump of claim 1 disposed within the chassis, wherein the outlet of the conduit of the pump is fluidically coupled with the cold plate.

15. The information processing device of claim 14,
wherein the information processing device is a server and the information processing component is a processor.

16. An information processing system, comprising:
a plurality of information processing devices, each comprising: a chassis; a system board disposed in the chassis; an information processing component coupled to the system board; a cold plate thermally coupled to the information processing component; and at least one pump according to claim 1 disposed in the chassis with the outlet of the conduit of the pump fluidically coupled with the cold plate; and
an external liquid cooling system comprising liquid coolant supply lines configured to supply liquid coolant to the pumps of the information processing devices, liquid coolant return lines configured to return liquid coolant from the pumps, and a coolant chilling unit configured to cool the liquid coolant.

17. The system of claim 16,
wherein the pumps are individually controllable to individually adjust the flow rate of the liquid coolant through the information processing devices.

18. A method of manufacturing a pump, comprising:
providing a partial impeller chamber defining an interior volume with an opening at an axial end thereof;
inserting an impeller/rotor subassembly into the interior volume of the partial impeller chamber via the opening, the impeller/rotor subassembly comprising an impeller and a rotor coupled to the impeller;
forming an impeller chamber from the partial impeller chamber by joining a cover to the partial impeller chamber over the opening to close the opening with the impeller/rotor subassembly contained in the interior volume;
coupling a printed circuit board (PCB) stator to the impeller chamber with the PCB stator axially adjacent the rotor and perpendicular to a rotation axis of the impeller/rotor subassembly.

19. The method of claim 18, wherein the cover comprises an end wall and coupling the PCB stator to the impeller chamber comprises coupling the PCB stator to the end wall outside of the impeller chamber after closing the opening.

20. The method of claim 18, wherein the end wall comprises a stator chamber, and coupling the PCB stator to the impeller chamber comprises coupling the PCB stator to the stator chamber prior to closing the opening such that the PCB stator is inside the impeller chamber.
